(19) United States
(12) Patent Application Publication
(10) Pub. No.: US 2013/0277203 A1
(43) Pub. Date: Oct. 24, 2013

(54) PROCESS KIT SHIELD AND PHYSICAL VAPOR DEPOSITION CHAMBER HAVING SAME

(71) Applicant: APPLIED MATERIALS, INC., Santa Clara, CA (US)

(72) Inventors: MUHAMMAD RASHEED, San Jose, CA (US); ADOLPH MILLER ALLEN, Oakland, CA (US); JIANQI WANG, Fremont, CA (US)

(21) Appl. No.: 13/860,578

(22) Filed: Apr. 11, 2013

Related U.S. Application Data
(60) Provisional application No. 61/637,606, filed on Apr. 24, 2012.

(51) Int. Cl. C23C 14/34

(52) U.S. Cl. CPC C23C 14/34
USPC 204/192.1; 204/298.11

(57) ABSTRACT

Embodiments of process kit shields and physical vapor deposition (PVD) chambers incorporating same are provided herein. In some embodiments, a process kit shield for use in depositing a first material in a physical vapor deposition process may include an annular body defining an opening surrounded by the body, wherein the annular body is fabricated from the first material, and an etch stop coating formed on opening-facing surfaces of the annular body, the etch stop coating is fabricated from a second material that is different from the first material, the second material having a high etch selectivity with respect to the first material.

### CROSS-REFERENCE TO RELATED APPLICATIONS

This application claims benefit of U.S. provisional patent application Ser. No. 61/637,606, filed Apr. 24, 2012, which is herein incorporated by reference in its entirety.

### FIELD

Embodiments of the present invention generally relate to substrate processing equipment, and more specifically to process kit shields for use in substrate processing equipment.

### BACKGROUND

A process kit shield may be used in, for example, a physical vapor deposition (PVD) chamber to separate a processing volume from a non-processing volume. In PVD chambers configured to deposit aluminum on a substrate, the shield may be fabricated from stainless steel (SST). This allows shield to be able to recycled multiple times as an aluminum layer deposited on the shield during processing can be preferentially etched away from the base SST shield material. However, the inventors have been working on depositing very thick aluminum films on the substrate, requiring significantly increased process power and deposition time as compared to conventional aluminum deposition processes. For the thicker aluminum deposition process, the inventors have observed that the temperature of the process kit shield goes sufficiently high to undesirably result in whisker growth on the substrate, which is a poor attribute of the deposited film.

Accordingly, the inventors have provided embodiments of a process kit shield as disclosed herein.

### SUMMARY

Embodiments of process kit shields and physical vapor deposition (PVD) chambers incorporating same are provided herein. In some embodiments, a process kit shield for use in depositing a first material in a physical vapor deposition process may include an annular body defining an opening surrounded by the body, wherein the annular body is fabricated from the first material, and an etch stop coating formed on opening-facing surfaces of the annular body, the etch stop coating is fabricated from a second material that is different from the first material, the second material having a high etch selectivity with respect to the first material.

In some embodiments, an apparatus for depositing a first material on a substrate may include a process chamber having a processing volume and a non-processing volume, a substrate support disposed in the process chamber, a target disposed in the process chamber opposite the substrate support, the target including a first material to be deposited on a substrate, and a process kit shield disposed in the process chamber and separating the processing volume from the non-processing volume, the process kit shield including, an annular body defining an opening surrounded by the body, wherein the annular body is fabricated from the first material, and an etch stop coating formed on opening-facing surfaces of the annular body, the etch stop coating is fabricated from a second material that is different from the first material, the second material having a high etch selectivity with respect to the first material.

In some embodiments, a method for processing a substrate using a process kit shield in a physical vapor deposition (PVD) chamber may include depositing a first material on a substrate in a PVD chamber having a process kit shield including an annular body defining an opening surrounded by the body, wherein the annular body is fabricated from the first material, and an etch stop coating formed on opening-facing surfaces of the annular body, the etch stop coating is fabricated from a second material that is different from the first material, the second material having a high etch selectivity with respect to the first material, removing the process kit shield from the PVD chamber, selectively removing the first material deposited on the etch stop coating due to depositing a first material on a substrate while predominantly leaving the etch stop coating on the surfaces of the body, removing the etch stop coating from the surfaces from the body, and depositing a second etch stop coating on the surfaces of the body, the second etch stop coating is fabricated from a third material having a high etch selectivity with respect to the first material.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross sectional view of a process chamber in accordance with some embodiments of the present invention.

FIG. 2 depicts a schematic cross section view of a process kit shield in accordance with some embodiments of the present invention.

FIG. 3 depicts a flow diagram of a method of using a process kit shield in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of process kit shields and physical vapor deposition (PVD) chambers incorporating same are provided herein. In some embodiments, a process kit shield may include a coating on an annular aluminum body for use in depositing aluminum in a PVD chamber and which enables the process kit shield to be easily recyclable. The coating over the aluminum body acts as an etch stop for ease of removal of the aluminum deposited during the PVD process.

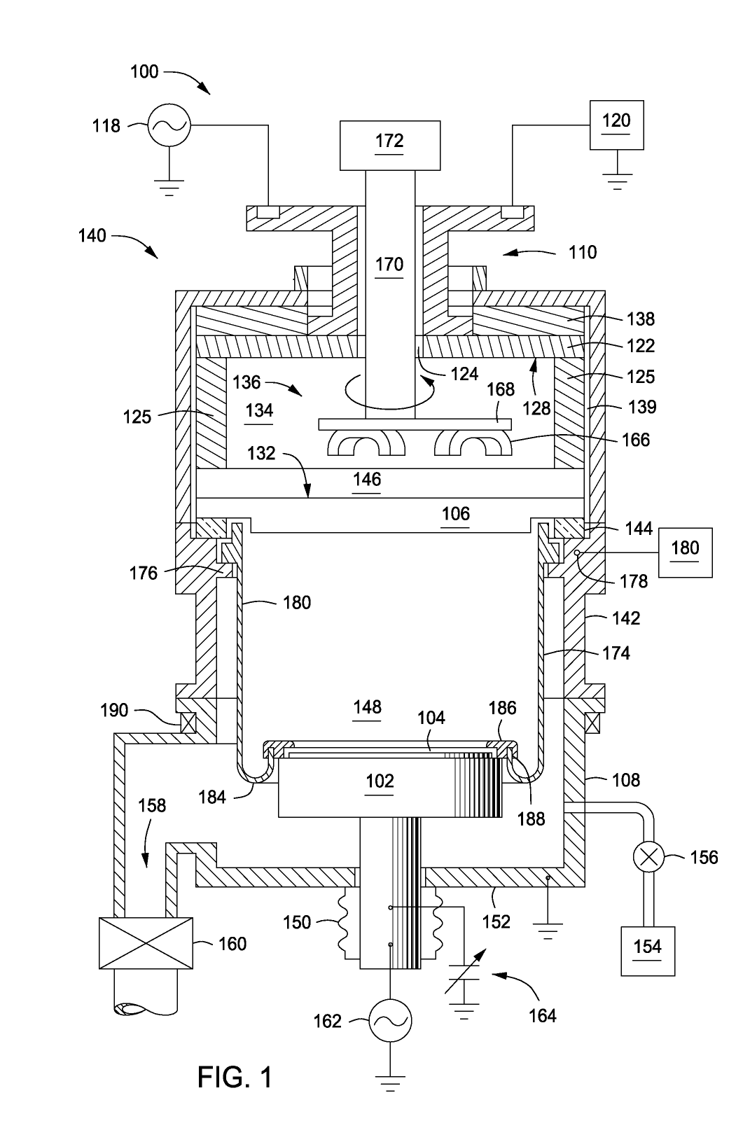

FIG. 1 depicts a schematic, cross-sectional view of an illustrative physical vapor deposition chamber (process chamber 100) having a process kit shield in accordance with some embodiments of the present invention. Examples of PVD chambers suitable for use with process kit shields of the present invention include the ALPS® Plus, SIP ENCORE®, and other PVD processing chambers commercially available from Applied Materials, Inc., of Santa Clara, Calif. Other processing chambers from Applied Materials, Inc. or other manufactures may also benefit from the inventive apparatus disclosed herein.

The process chamber 100 contains a substrate support pedestal 102 for receiving a substrate 104 thereon, a sputtering source, such as a target 106, and a process kit shield 174 disposed between the substrate support pedestal 102 and the target 106. The substrate support pedestal 102 may be located within a grounded enclosure wall 108, which may be a chamber wall (as shown) or a grounded shield (a ground shield 140 is shown covering at least some portions of the process chamber 100 above the target 106. In some embodiments, the ground shield 140 could be extended below the target to enclose the pedestal 102 as well).

In some embodiments, the process chamber 100 may include a feed structure 110, or other suitable feed structure for coupling either or both of RF and DC energy to the target 106. The feed structure is an apparatus for coupling RF and/or DC energy to the target, or to an assembly containing the target, for example, as described herein.

In some embodiments, a first end of the feed structure 110 can be coupled to a DC power source 120 which can be used to provide DC energy to the target 106. For example, the DC power source 120 may be utilized to apply a negative voltage, or bias, to the target 106.

Alternatively, or in combination, the first end of the feed structure 110 can be coupled to an RF power source 118 which can be used to provide RF energy to the target 106. In some embodiments, RF energy supplied by the RF power source 118 may range in frequency from about 2 MHz to about 60 MHz, or, for example, non-limiting frequencies such as 2 MHz, 13.56 MHz, 27.12 MHz, or 60 MHz can be used. In some embodiments, a plurality of RF power sources may be provided (i.e., two or more) to provide RF energy in a plurality of the above frequencies.

In some embodiments, a first end of the feed structure 110 can be coupled to an RF power source 118 which can be utilized to provide RF energy to the target 106. In combination, the first end of the feed structure 110 can also be coupled to the DC power source 120 which can be utilized to provide DC energy to the target 106. In some embodiments, RF energy supplied by the RF power source 118 may range in frequency from about 2 MHz to about 60 MHz, or, for example, non-limiting frequencies such as 2 MHz, 13.56 MHz, 27.12 MHz, or 60 MHz can be used. In some embodiments, a plurality of RF power sources may be provided (i.e., two or more) to provide RF energy in a plurality of the above frequencies.

The feed structure 110 may be coupled to the target 106, for example, via a source distribution plate 122 and a conductive member 125 coupled between the source distribution plate 122 and the target 106. A cavity 134 may be defined by the inner-facing walls of the conductive member 125, the target-facing surface 128 of the source distribution plate 122 and the source distribution plate-facing surface 132 of the target 106. The cavity 134 may be utilized to at least partially house one or more portions of a rotatable magnetron assembly 136 (discussed below). In some embodiments, the cavity may be at least partially filled with a cooling fluid, such as water (H₂O) or the like.

A ground shield 140 may be provided to cover the outside surfaces of the lid of the process chamber 100. The ground shield 140 may be coupled to ground, for example, via the ground connection of the chamber body. The ground shield 140 may comprise any suitable conductive material, such as aluminum, copper, or the like. An insulative gap 139 is provided between the ground shield 140 and the outer surfaces of the distribution plate 122, the conductive member 125, and the target 106 (and/or backing plate 146) to prevent the RF and/or DC energy from being routed directly to ground. The insulative gap may be filled with air or some other suitable dielectric material, such as a ceramic, a plastic, or the like.

An isolator plate 138, or a plurality of isolator features, may be disposed between the source distribution plate 122 and the ground shield 140 to prevent the RF and/or DC energy from being routed directly to ground. The isolator plate 138 may comprise a suitable dielectric material, such as a ceramic, a plastic, or the like. Alternatively, an air gap may be provided in place of the isolator plate 138. In embodiments where an air gap is provided in place of the isolator plate, the ground shield 140 may be structurally sound enough to support any components resting upon the ground shield 140.

The target 106 may illustratively be supported on a grounded, conductive sidewall of the chamber, referred to in some embodiments as an adapter 142, through a dielectric isolator 144. In some embodiments, the grounded, conductive sidewall of the chamber, or adapter 142, may be fabricated from aluminum. The target 106 comprises a material to be deposited on the substrate 104 during sputtering, such a metal or metal oxide. In some embodiments, the backing plate 146 may be coupled to the source distribution plate-facing surface 132 of the target 106. The backing plate 146 may comprise a conductive material, such as copper-zinc, copper-chrome, or the same material as the target, such that RF and/or DC energy can be coupled to the target 106 via the backing plate 146. Alternatively, the backing plate 146 may be non-conductive and may include conductive elements such as electrical feedthroughs or the like for coupling the target 106 to the conductive member 125. The backing plate 146 may be included for example, to improve structural stability of the target 106.

A rotatable magnetron assembly 136 may be positioned proximate a back surface (e.g., source distribution plate-facing surface 132) of the target 106. The rotatable magnetron assembly 136 includes a plurality of magnets 166 supported by a base plate 168. The base plate 168 connects to a rotation shaft 170, disposed through opening 124, coincident with the central axis of the process chamber 100 and the substrate 104. A motor 172 can be coupled to the upper end of the rotation shaft 170 to drive rotation of the magnetron assembly 136. The magnets 166 produce a magnetic field within the process chamber 100, generally parallel and close to the surface of the target 106 to trap electrons and increase the local plasma density, which in turn increases the sputtering rate. The magnets 166 produce an electromagnetic field around the top of the process chamber 100, and magnets 166 are rotated to rotate the electromagnetic field which influences the plasma density of the process to more uniformly sputter the target 106. For example, the rotation shaft 170 may make about 0 to about 150 rotations per minute.

The substrate support pedestal 102 has a material-receiving surface facing the principal surface of the target 106 and supports the substrate 104 to be sputter coated in planar position opposite to the principal surface of the target 106. The substrate support pedestal 102 may support the substrate 104 in a central region 148 of the process chamber 100. The central region 148 is defined as the region above the substrate support pedestal 102 during processing (for example, between the target 106 and the substrate support pedestal 102 when in a processing position).

In some embodiments, the substrate support pedestal 102 may be vertically movable through a bellows 150 connected to a bottom chamber wall 152 to allow the substrate 104 to be transferred onto the substrate support pedestal 102 through a load lock valve in the lower portion of processing the process chamber 100 and thereafter raised to a deposition, or processing position. One or more processing gases may be supplied from a gas source 154 through a mass flow controller 156 into the lower part of the process chamber 100. An exhaust port 158 may be provided and coupled to a pump via a valve 160 for exhausting the interior of the process chamber 100 and facilitating maintaining a desired pressure inside the process chamber 100.

In some embodiments, an RF bias power source 162 may be coupled to the substrate support pedestal 102 in order to induce a negative DC bias on the substrate 104. In addition, in some embodiments, a negative DC self-bias may form on the substrate 104 during processing. For example, RF power supplied by the RF bias power source 162 may range in frequency from about 2 MHz to about 60 MHz, for example, non-limiting frequencies such as 2 MHz, 13.56 MHz, or 60 MHz can be used. In other applications, the substrate support pedestal 102 may be grounded or left electrically floating. In some embodiments, a capacitance tuner 164 may be coupled to the substrate support pedestal for adjusting voltage on the substrate 104 for applications where RF bias power may not be desired.

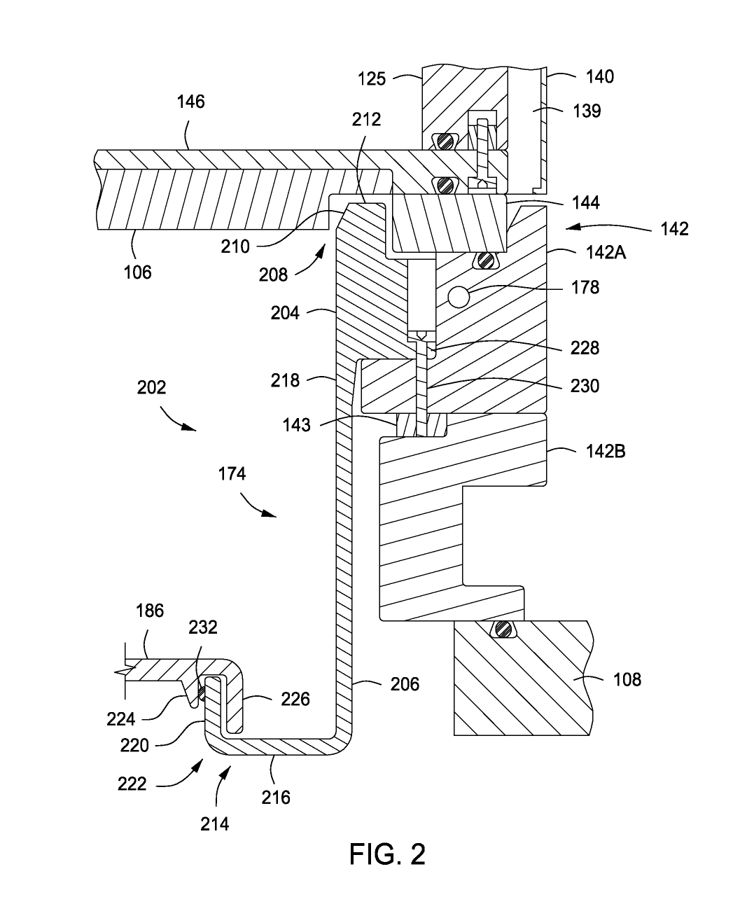

The process kit shield 174 may be coupled to the process chamber 100 in any suitable manner for retaining the process kit shield 174 in a desired position within the process chamber 100. For example, in some embodiments the process kit shield 174 may be connected to a ledge 176 of the adapter 142. The adapter 142 in turn is sealed and grounded to the aluminum chamber sidewall 108. Generally, the process kit shield 174 extends downwardly along the walls of the adapter 142 and the chamber wall 108 downwardly to below a top surface of the substrate support pedestal 102 and returns upwardly until reaching a top surface of the substrate support pedestal 102 (e.g., forming a u-shaped portion 184 at the bottom). Alternatively, the bottom-most portion of the process kit shield need not be a u-shaped portion 184 and may have any suitable shape. A cover ring 186 may rest on the top of an upwardly extending lip 188 of the process kit shield 174 when the substrate support pedestal 102 is in its lower, loading position. The cover ring 186 rests on the outer periphery of the substrate support pedestal 102 when it is in its upper, deposition position to protect the substrate support pedestal 102 from sputter deposition. One or more additional deposition rings may be used to shield the periphery of the substrate 104 from deposition. Embodiments of the process kit shield 174 in accordance with the present invention are discussed below with respect to FIG. 2.

In some embodiments, one or more heat transfer channels 178 may be provided within (as shown), or adjacent to, the adapter 142 to transfer heat to and/or from the adapter 142. The one or more heat transfer channels 178 may be coupled to a heat transfer fluid supply 180 that may circulate a heat transfer fluid through the one or more heat transfer channels 178. In some embodiments, the heat transfer fluid may be a coolant, such as water, or other suitable coolant. The heat transfer fluid supply 180 may maintain the heat transfer fluid at or near a desired temperature to facilitate the transfer of heat to or from the adapter 142. Controlling the temperature of the adapter 142 advantageously facilitates controlling the temperature of the process kit shield 174. For example, removing heat from the process kit shield 174 during processing reduces the temperature gradient of the process kit shield 174 between processing and idle or off states of the chamber, which reduces particle generation that could arise due to thermal coefficient of thermal expansion mismatch of the process kit shield 174 and any deposited materials that may be present on the process kit shield 174.

In some embodiments, a magnet 190 may be disposed about the process chamber 100 for selectively providing a magnetic field between the substrate support pedestal 102 and the target 106. For example, as shown in FIG. 1, the magnet 190 may be disposed about the outside of the chamber wall 108 in a region just above the substrate support pedestal 102 when in processing position. In some embodiments, the magnet 190 may be disposed additionally or alternatively in other locations, such as adjacent the adapter 142. The magnet 190 may be an electromagnet and may be coupled to a power source (not shown) for controlling the magnitude of the magnetic field generated by the electromagnet.

The process kit shield generally comprises an annular aluminum body having a coating formed on surfaces of the body where aluminum may be deposited during an aluminum PVD deposition process. The process kit shield is more easily recyclable due to the high etch selectivity between the aluminum being removed and the material of the etch stop coating. As used herein, high etch selectivity is related to different etching rate ratios between chemically different materials such as the annular body material and the etch stop coating material that is sufficient to facilitate substantially complete removal of the deposited material, which may be the same as the annular body material, without etching through the etch stop coating material. For example, the etch stop coating may comprise titanium or other metal or oxide coating over the aluminum body that can act as an etch stop for aluminum deposition removal, where the deposited aluminum can be removed without etching through the titanium or other metal or oxide coating (i.e., the etch stop coating).

FIG. 2 depicts a schematic cross section view of the process kit shield 174 in accordance with some embodiments of the present invention. The process kit shield 174 includes a body 202 having an upper portion 204 and a lower portion 206. In some embodiments, the body 202 may be a one-piece body. Providing a one-piece body may advantageously eliminate additional surfaces, such as those formed from having a process kit shield formed of multiple pieces, where flaking of deposited materials can occur. In some embodiments, a gap 208 formed between target-facing surfaces 210, 212 of the upper portion 204 may have a size suitable to prevent arcing between the process kit shield 174 and the target 106. In some embodiments, the distance of the gap 208 may be between about 0.25 to about 4 mm, or about 2 mm.

In conventional PVD processes, for example, for depositing aluminum, process kits shields may be fabricated from materials such as stainless steel (SST). However, the inventors have discovered that, when depositing thick layers of aluminum, the temperature of such conventional process kit shields goes sufficiently high to undesirably result in whisker growth on the substrate, which is a poor attribute of the deposited film. Furthermore, it has been found that the higher thermal conductivity of aluminum over materials such as SST allows for higher operating powers due to a relative decrease in thermal expansion of the shield. As thermal expansion of the shield in the direction of the target can result in undesirable arcing across the high voltage gap from shield to target, a reduction in the thermal expansion advantageously facilitates providing a wider process window (e.g., a wider range of operating power that may be used).

Accordingly, in some embodiments, the body 202 of the process kit shield 174 may be fabricated from aluminum. In addition, at least process volume facing surfaces of the process kit shield 174, e.g., surface 218, may be coated with a layer of material that has a high etch selectivity to aluminum, such as one or more of titanium, tantalum, nickel, titanium oxide, or the like. The layer 218 may be deposited in any suitable fashion, such as by plasma spraying. In some embodiments, the purity of the titanium layer 218 is >99%. The plasma spray may be performed in an inert or vacuum (e.g., no oxygen) environment to enhance the purity of coating. The process can be performed in vacuum environment also to enhance the purity and density of the coating. The thickness of the coating layer 218 may be between about 0.008 to about 0.012 inches. The thickness can also be greater to enhance recyclability performance.

Further, the surface roughness of the layer 218 may range from about 250 to about 400 micro inches roughness average (Ra), such that any film formed on the coating during processing has limited potential to flake off and contaminate a substrate being processed.

The upper portion 204, for example which may be used to replace a ceramic portion of a conventional process kit shield, is spaced apart from surfaces of the target 106 by the gap 208 such that arcing is limited between the surfaces of the target 106 and target-facing surfaces 210, 212 of the upper portion 204. For example, one or more of the target-facing surfaces may be configured to limit particle formation while maintaining a suitable gap distance to limit arcing. For example, the target-facing surface 210 may be a contoured target-facing surface having any suitably shaped contoured surface to limit particles from collecting on, or low energy deposition of material on, the target-facing surface 212. The contoured target-facing surface may limit a direct line of sight or create a torturous path whereby a particle of the target material, or low energy deposition of the target material, will not reach the horizontal target-facing surface 212 of the upper portion of the process kit shield 174. For example, in some embodiments, the contoured target-facing surface may extend generally inward, e.g., toward the target 106, or may extend generally outward, e.g., away from the target 106. Other geometries of the contoured target-facing surface 302 may also be used. Further, in some embodiments, a target surface adjacent the contoured target-facing surface may be shaped to generally match the contoured shape of the contoured target-facing surface. Alternatively, a surface of the target 106 adjacent the contoured target-facing surface may not be contoured to match the contoured shape of the contoured target-facing surface.

The lower portion 206 of the body 202 includes a lip assembly 214 which interfaces with the cover ring 186. For example, the lip assembly 214 may include a lower surface 216 extending inward from a lower edge of the lower portion 206 of the body 202. As discussed above, the lower surface 216 may take on any suitable shape, such as the u-shaped portion 184 as illustrated in FIG. 1. The lip assembly 214 includes a lip 220 disposed about an inner edge 222 of the lower surface 216 and extending upward from the inner edge 222 of the lower surface towards the upper portion 204 of the body 202. In some embodiments, the lip 220 may extend upwards between adjacent and downward extending inner and outer lips 224, 226 of the cover ring 186.

The lengths of the inner and outer lips 224, 226 of the cover ring 186 and the length of the lip 220 may vary depending on the type of processes being performed in the process chamber 100. For example, in high pressure processes, for example at pressures ranging from about 1 mTorr to about 500 mTorr, the movement of the substrate support may be limited. Accordingly, in high pressure processes, the lip 220 may be about 1 inch in length. Further, the range of motion of the substrate support during a high pressure process may be about 15 mm or less. The lengths of the inner and outer lips 224, 226 may be any suitable length sufficient to cover the range of motion of the substrate support while remaining overlapped with lip 220. The minimum overlap between the lip 220 and at least the outer lip 226 may be about 0.25 inches.

In some embodiments, for example during low pressure processes where the pressure ranging from about 1 mTorr to about 500 mTorr, the lip 220 and the inner and outer lips 224, 226 may be shorter than during high pressure processes. For example, in low pressure processes, the lip 220 may range from about 0 inches to about 5 inches, or about 2.2 inches, in length. Further, in some embodiments, the range of motion of the substrate support during a high pressure process may be about 40 mm (about 1.57 inches) or less. The lengths of the inner and outer lips 224, 226 may be any suitable length sufficient to cover the range of motion of the substrate support while remaining overlapped with lip 220. The minimum overlap between the lip 220 and at least the outer lip 226 may be about 0 inches to about 5 inches.

In some embodiments, the process kit shield 174 may also include a plurality of alignment features 232 (one shown in FIG. 2) disposed about an inner lip-facing surface of the lip 220. The alignment features 232 may align the lip 220 to contact the outer lip 226 of the cover ring 186. For example, the lip 220 may be advantageously aligned to contact the outer lip 226 to form a good seal between the lip 220 and the outer lip 226 to maintain pressure in the processing volume or the like. In some embodiments, the alignment features 232 may advantageously provide concentricity between the cover ring 186 and the process kit shield 174 to define a uniform gap disposed between the cover ring 186 and the process kit shield 174. The uniform gap provide more uniform flow conductance of any gases that may be provided from a lower portion of the chamber.

In some embodiments, each alignment feature 232 may be a rounded feature, such as a ball. The alignment feature 232 may comprise stainless steel, aluminum, or the like. The alignment feature 232 contacts the surface of the inner lip 224 of the cover ring 186. At least a portion of the alignment feature 232 in contact with the inner lip 224 may be formed of a hard material, for example, sapphire, stainless steel, alumina, or the like to prevent flaking during contact with the inner lip 224. The alignment feature 232 may alternatively contact the surface of the outer lip 226 of the cover ring 186.

In some embodiments, the process kit shield 174 may be anchored to the adapter 142. For example, the adapter 142 may include an upper portion 142A and a lower portion 142B (also referred to as an upper adapter and a lower adapter). The upper portion 204 of the body 202 may rest on the upper portion 142A of the adapter 142. The upper portion 204 may include a plurality of holes 228 disposed about the upper portion 204 for placing a screw, bolt, or the like therethrough to secure the body 202 against the upper portion 142A of the adapter 142. The upper portion 142A of the adapter 142 similar includes a plurality of holes 230 which are adjacent to each hole 228 for placing the screw, bolt or the like therethrough. The holes 228, 230 may not be threaded, for example, to limit the possibility of virtual leaks due to gases that would become trapped between adjacent threads of the holes and a screw, bolt or the like. The adapter 142 further includes one or more anchoring devices 143 disposed about the body 202 and beneath each hole 230 to receive the screw, bolt, or the like from above the adapter 142A. In some embodiments, one anchoring device may be provided and may be an annular plate Each anchoring device 143 may comprise stainless steel or another hard material suitable for receiving the screw, bolt or the like. Each anchoring device 143 includes a threaded portion for securing the screw, both, or the like. In some embodiments, sufficient contact surface area is provided between the process kit shield 174 and the process chamber to facilitate increased heat transfer from the process kit shield 174 in order to reduce the shield temperature. For example, in some embodiments, greater than 12, or in some embodiments, about 36 mounting bolts or the equivalent may be used to provide more contact surface. In some embodiments, the adapter 142A that the shield mounts to may be water cooled to facilitate removing heat from the process kit shield 174.

Embodiments of the process kit shields described herein are particularly useful for depositing aluminum in a PVD chamber, such as the process chamber 100 described above. The process kit shields in accordance with the present invention may advantageously enable depositing thicker aluminum films, such as pure aluminum, on a substrate without higher shield temperatures, thereby preventing undesired whisker growth on the deposited film. Furthermore, after depositing pure aluminum on the aluminum process kit shield, the process kit shield can be cleaned and recycled due to the titanium coating deposited over the aluminum body which enables the aluminum film from the PVD deposition process to be removed, or etched preferentially, from the process kit shield.

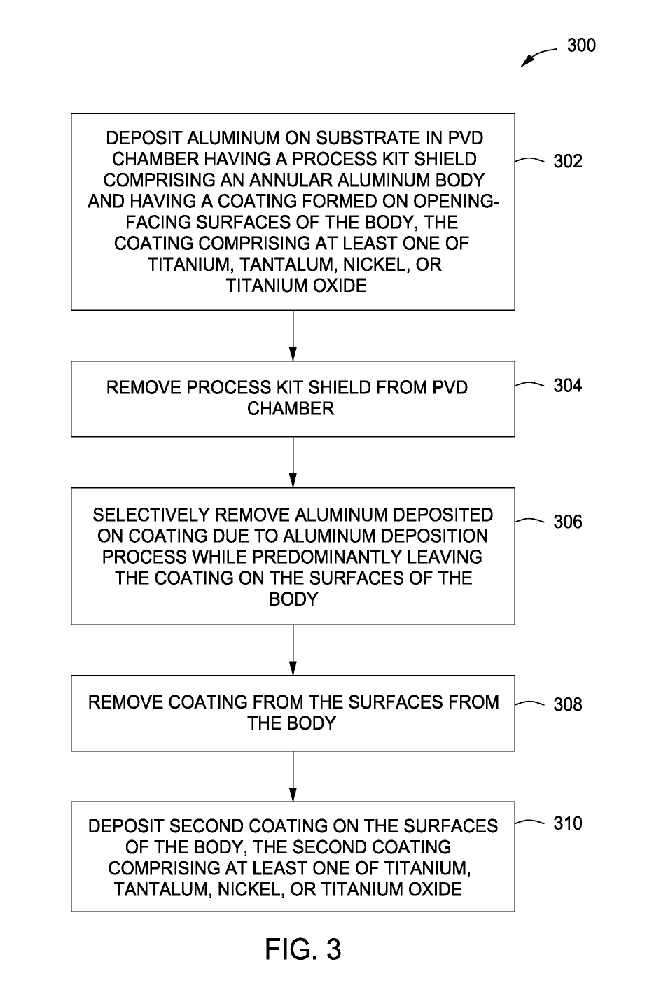

For example, FIG. 3 depicts a method 300 for processing a substrate using a process kit shield in a physical vapor deposition (PVD) chamber, such as the process kit shield 174 and the process chamber 100, described above.

The method 300 generally begins at 302 where aluminum is deposited on a substrate (e.g., 104) in a PVD chamber (e.g., 100) having a process kit shield (e.g., 174) comprising an annular aluminum body defining an opening surrounded by the body and having a coating formed on opening-facing surfaces of the body, the coating comprising at least one of titanium, tantalum, nickel, niobium, molybdenum, or titanium oxide.

After one or more process runs of depositing aluminum on a substrate, sufficient aluminum may be deposited on the process kit shield 174 such that the process kit shield 174 needs to be cleaned or replaced in order to maintain process quality, for example, to avoid particle deposition on the substrate from materials flaking off of the process kit shield. Thus, at 304, the process kit shield may be removed from the PVD chamber and, at 306, the aluminum deposited on the coating due to the aluminum deposition process may be selectively removed while predominantly leaving the coating (e.g., layer 218) on the surfaces of the body of the process kit shield. The deposited aluminum may be completely or substantially completely removed from the coating (e.g., layer 218), for example, by etching the aluminum away using a suitable etchant with a selectivity for etching aluminum over the material of the coating (e.g., titanium or other materials as discussed above).

Next, at 308, the coating (e.g., layer 218) may be removed from the surfaces from the body. The coating may be completely or substantially completely removed from the body, for example, by etching the material away using a suitable etchant having a selectivity for etching the material of the coating (e.g., titanium or other materials as discussed above) over aluminum or by bead blasting the coating using a suitable abrasive media.

Next, at 310, a second coating may be deposited on the surfaces of the body. The second coating may be the same as the first layer 218, for example, comprising at least one of titanium, tantalum, niobium, molybdenum, nickel, or titanium oxide. Upon completion of 310, the recycled process kit shield 174 may now again be installed in the process chamber 100 to be used during aluminum PVD deposition processes.

While the foregoing is directed to embodiments of the present invention, other and further embodiments of the invention may be devised without departing from the basic scope thereof.

1. A process kit shield for use in depositing a first material in a physical vapor deposition process, comprising:
an annular body defining an opening surrounded by the body, wherein the annular body is fabricated from the first material; and
an etch stop coating formed on opening-facing surfaces of the annular body, the etch stop coating is fabricated from a second material that is different from the first material, the second material having a high etch selectivity with respect to the first material.

2. The process kit shield of claim 1, wherein the first material is aluminum.

3. The process kit shield of claim 2, wherein the second material is at least one of titanium, tantalum, nickel, niobium, molybdenum, or titanium oxide.

4. The process kit shield of claim 2, wherein the second material is a titanium coating having a purity greater than 99%.

5. The process kit shield of claim 1, wherein a thickness of the etch stop coating is about 0.008 inches to about 0.012 inches.

6. The process kit shield of claim 1, wherein a surface roughness of the etch stop coating is about 250 micro inches to about 400 micro inches roughness average (Ra).

7. The process kit shield of claim 1, further comprising:
a lower portion of the body including a lip assembly, wherein the lip assembly includes a lower surface extending inward from a lower edge of the lower portion of the body.

8. The process kit shield of claim 7, wherein the lip assembly further includes a lip disposed about an inner edge of the lower surface of the body, and extending upward from the inner edge of the lower surface towards an upper portion of the body.

9. An apparatus for depositing a first material on a substrate, comprising:
a process chamber having a processing volume and a non-processing volume;
a substrate support disposed in the process chamber;
a target disposed in the process chamber opposite the substrate support, the target including a first material to be deposited on a substrate; and
a process kit shield disposed in the process chamber and separating the processing volume from the non-processing volume, the process kit shield comprising:
an annular body defining an opening surrounded by the body, wherein the annular body is fabricated from the first material; and
an etch stop coating formed on opening-facing surfaces of the annular body, the etch stop coating is fabricated from a second material that is different from the first material, the second material having a high etch selectivity with respect to the first material.

10. The apparatus of claim 9, wherein the first material is aluminum.

11. The apparatus of claim 10, wherein the second material is at least one of titanium, tantalum, nickel, niobium, molybdenum, or titanium oxide.

12. The apparatus of claim 10, wherein the second material is a titanium coating having a purity greater than 99%.

13. The apparatus of claim 9, wherein a thickness of the etch stop coating is about 0.008 inches to about 0.012 inches.

14. The apparatus of claim 9, wherein a surface roughness of the etch stop coating is about 250 micro inches to about 400 micro inches roughness average (Ra).

15. The apparatus of claim 9, further comprising:
a lower portion of the body including a lip assembly, wherein the lip assembly includes a lower surface extending inward from a lower edge of the lower portion of the body.

16. The apparatus of claim 15, wherein the lip assembly further includes a lip disposed about an inner edge of the lower surface of the body, and extending upward from the inner edge of the lower surface towards an upper portion of the body.

17. A method for processing a substrate using a process kit shield in a physical vapor deposition (PVD) chamber, comprising:
depositing a first material on a substrate in a PVD chamber having a process kit shield comprising:
an annular body defining an opening surrounded by the body, wherein the annular body is fabricated from the first material, and
an etch stop coating formed on opening-facing surfaces of the annular body, the etch stop coating is fabricated from a second material that is different from the first material, the second material having a high etch selectivity with respect to the first material;
removing the process kit shield from the PVD chamber;
selectively removing the first material deposited on the etch stop coating due to depositing a first material on a substrate while predominantly leaving the etch stop coating on the surfaces of the body;
removing the etch stop coating from the surfaces from the body; and
depositing a second etch stop coating on the surfaces of the body, the second etch stop coating is fabricated from a third material having a high etch selectivity with respect to the first material.

18. The method of claim 17, wherein the first material is aluminum.

19. The method of claim 18, wherein the second and third materials are at least one of titanium, tantalum, nickel, niobium, molybdenum, or titanium oxide.

20. The method of claim 19, wherein the etch stop coating is deposited on the opening-facing surfaces of the annular body by plasma spraying performed in an inert or vacuum environment to enhance a purity level of the etch stop coating.
